(19) United States
(12) Patent Application Publication
(10) Pub. No.: US 2026/0068099 A1
(43) Pub. Date: Mar. 5, 2026

(54) CONTROL APPARATUS FOR VEHICLE

(71) Applicant: HYUNDAI MOBIS CO., LTD., Seoul (KR)

(72) Inventor: Byeong Jun KANG, Seoul (KR)

(73) Assignee: HYUNDAI MOBIS CO., LTD., Seoul (KR)

(21) Appl. No.: 19/219,660

(22) Filed: May 27, 2025

(30) Foreign Application Priority Data
Sep. 5, 2024 (KR) 10-2024-0120722

(51) Int. Cl. H05K 7/20

(52) U.S. Cl. CPC H05K 7/20509; H05K 7/20481; H05K 7/2049; H05K 7/20518; H05K 7/20854; H05K 7/20409

(57) ABSTRACT

Disclosed is a control apparatus for a vehicle. According to an embodiment of the present disclosure, there is provided a control apparatus for a vehicle comprising a first heat generation source including a first chip emitting heat energy and a first thermal interface material disposed on the first chip a second heat generation source including a second chip emitting more heat energy than the first chip and a second thermal interface material disposed on the second chip, a circuit board on which the first heat generation source and the second heat generation source are mounted, a heat transfer member including a plate extending outward from the second heat generation source and a through-hole formed at a position corresponding to the second heat generation source, and disposed on the first heat generation source, a third thermal interface material disposed on an end of the heat transfer member, and a heat sink disposed in contact with the second heat generation source and the third thermal interface material to dissipate heat.

### CROSS-REFERENCE TO RELATED APPLICATION

This application claims the benefit of and priority to Korean Patent Application No. 10-2024-0120722, filed on Sep. 5, 2024, the entire disclosure(s) of which is hereby incorporated herein by reference in its entirety.

### TECHNICAL FIELD

The present disclosure relates to a control apparatus for a vehicle.

### BACKGROUND

The description of this part only provides the background information of the present disclosure without configuring the related art.

Various control apparatuses for a vehicle that control various systems and functions are installed in vehicles. For example, a control apparatus for a vehicle can control various functions such as an engine, a brake system, shifting, steering, a safety system, entertainment, and convenience functions.

As the performance of chips mounted on control apparatuses for a vehicle becomes more advanced, there is an increasing trend of control apparatuses for a vehicle equipped with high-heat-generating chips. Further, the degrees of heart generation may be different, depending on the types of chips.

Control apparatuses for a vehicle according to the related art dissipate heat generated from a high-heat-generating chip using a structure that functions as a heat sink for heat dissipation.

In detail, FIG. 1 is a cross-sectional view showing a heat dissipation structure of a control apparatus for a vehicle of the related art.

Referring to FIG. 1, when the same heat sink 130 is used to dissipate heat generated from general devices 121 disposed adjacent to a high-heat-generating chip 111, an unexpected heat dissipation path may be formed. The heat generated from the high-heat-generating chip 111 may transfer to the general devices 121 through the heat sink 130. In this case, there is a problem in that the heat dissipation efficiency of the heat sink 130 decreases, and furthermore, the maximum allowable temperature of the general devices 121 may be exceeded.

Further, the heights of devices are different in control apparatuses for a vehicle according to the related art, so separate post-processing such as adjusting the height of the heat sink 130 is applied, and accordingly, there is a problem in that the production process is complicated.

### SUMMARY

A main object of a control apparatus for a vehicle according to an embodiment is to maximize heat dissipation efficiency by uniformly dissipating heat to the entire of a heat sink by separating a heat dissipation path of a high-heat-generating chip and a heat dissipation path of a general device using a heat transfer member.

A main object of a control apparatus for a vehicle according to an embodiment is to improve the performance of the control apparatus for a vehicle by increasing the power consumption limit of a high-heat-generating chip by maximizing heat dissipation efficiency.

The objects of the present disclosure are not limited to the objects described above and other objects will be clearly understood by those skilled in the art from the following description.

### Solution to Problem

According to an embodiment of the present disclosure, there is provided a control apparatus for a vehicle comprising a first heat generation source including a first chip emitting heat energy and a first thermal interface material disposed on the first chip a second heat generation source including a second chip emitting more heat energy than the first chip and a second thermal interface material disposed on the second chip, a circuit board on which the first heat generation source and the second heat generation source are mounted, a heat transfer member including a plate extending outward from the second heat generation source and a through-hole formed at a position corresponding to the second heat generation source, and disposed on the first heat generation source, a third thermal interface material disposed on an end of the heat transfer member, and a heat sink disposed in contact with the second heat generation source and the third thermal interface material to dissipate heat.

### Advantageous Effects

The control apparatus for a vehicle according to an embodiment can maximize heat dissipation efficiency by uniformly dissipating heat to the entire of a heat sink by separating a heat dissipation path of a high-heat-generating chip and a heat dissipation path of a general device using a heat transfer member.

The control apparatus for a vehicle according to an embodiment can improve the performance of the control apparatus for a vehicle by increasing the power consumption limit of a high-heat-generating chip by maximizing heat dissipation efficiency.

### BRIEF DESCRIPTION OF THE DRAWINGS

FIG. 1 is a cross-sectional view showing a heat dissipation structure of a control apparatus for a vehicle of the related art.

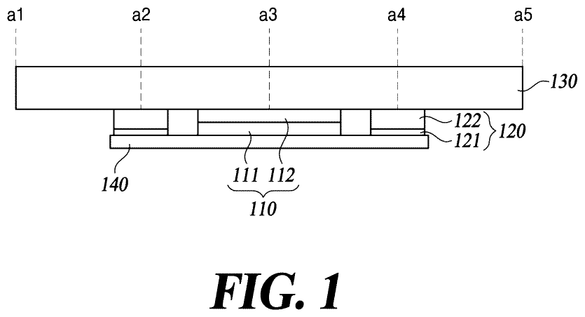

FIG. 2 is an exploded perspective view of a control apparatus for a vehicle according to a first embodiment of the present disclosure.

FIG. 3 is a cross-sectional view showing a heat dissipation structure and heat dissipation paths of the control apparatus for a vehicle according to the first embodiment of the present disclosure.

FIG. 4 is a cross-sectional view showing a heat dissipation structure and heat dissipation paths of a control apparatus for a vehicle according to a second embodiment of the present disclosure.

FIG. 5 is a cross-sectional view showing a heat dissipation structure of a control apparatus for a vehicle according to a third embodiment of the present disclosure.

FIG. 6 is a graph showing temperature according to the position of a heat sink in a control apparatus for a vehicle of the related art and the control apparatuses for a vehicle according to the first to third embodiments of the present disclosure.

FIG. 7 is a graph showing thermal resistance according to screw fastening force of the control apparatus for a vehicle according to the third embodiment of the present disclosure.

### DETAILED DESCRIPTION

Hereinafter, some embodiments of the present disclosure will be described in detail with reference to exemplary drawings. Note that when components in each drawing are denoted by reference numerals, the same components are denoted by the same numerals as much as possible even if they are denoted on different drawings. In addition, in describing the present disclosure, if it is determined that a specific description of a related known configuration or function may obscure the gist of the present disclosure, the detailed description thereof will be omitted.

In describing components of embodiments of the present disclosure, reference numerals such as first, second, i), ii), a), and b) may be used. These symbols are only used to distinguish the components from other components, and the nature, sequence, order, or the like of that component is not limited by the symbols. Throughout the specification, when it is stated that a certain portion “includes” or “comprises” a specific component, it shall be understood that, unless explicitly otherwise specified, this does not exclude other components but may further include additional components.

In describing components of the present disclosure, reference terms such as first, second, A, B, (a), and (b) may be used. These terms are only used to distinguish the components from other components, and the nature, sequence, order, or the like of that component is not limited by the terms. Where an element is described as being “connected,” “coupled” or “accessed” to another element, it will be understood that the element may be directly connected or connected to the other element, but that another element may also be “connected,” “coupled” or “accessed”between each element.

Unless otherwise specified, it should be understood that the description of one embodiment may be applied to other embodiments.

The following detailed description, together with the accompanying drawings, is intended to describe exemplary embodiments of the present disclosure, and is not intended to represent the only embodiments in which the present disclosure may be practiced.

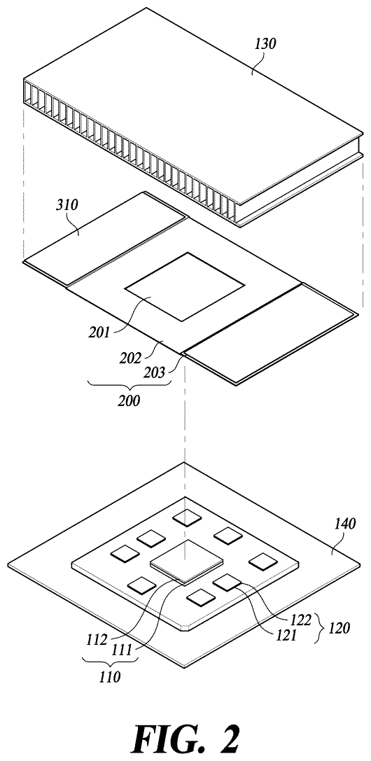

FIG. 2 is an exploded perspective view of a control apparatus for a vehicle according to a first embodiment of the present disclosure.

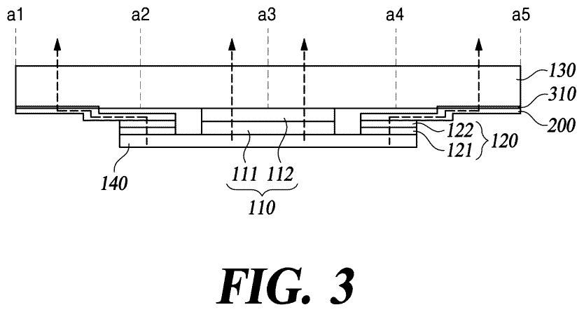

FIG. 3 is a cross-sectional view showing a heat dissipation structure and heat dissipation paths of the control apparatus for a vehicle according to the first embodiment of the present disclosure.

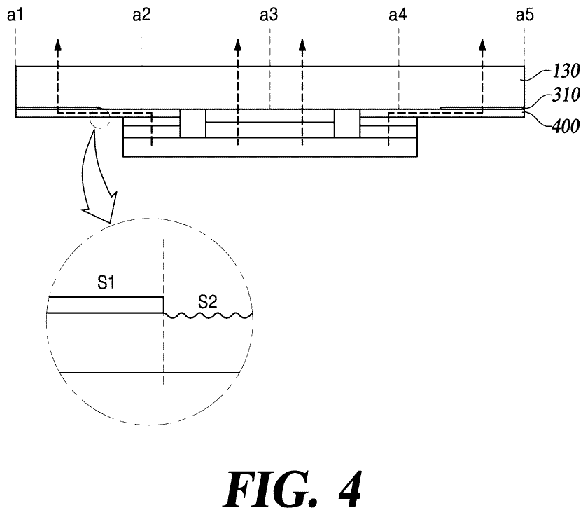

FIG. 4 is a cross-sectional view showing a heat dissipation structure and heat dissipation paths of a control apparatus for a vehicle according to a second embodiment of the present disclosure.

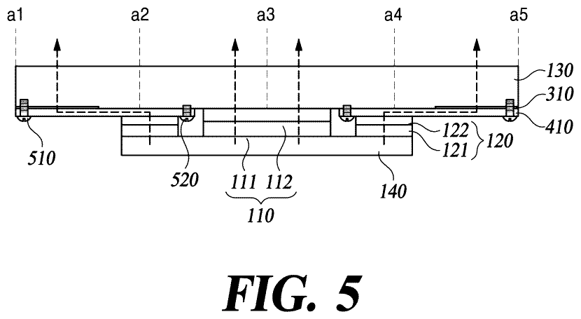

FIG. 5 is a cross-sectional view showing a heat dissipation structure of a control apparatus for a vehicle according to a third embodiment of the present disclosure.

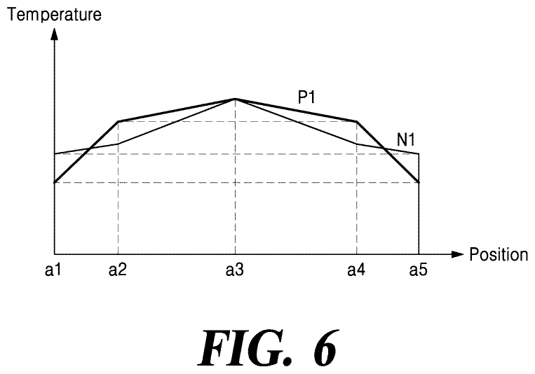

FIG. 6 is a graph showing temperature according to the position of a heat sink in a control apparatus for a vehicle of the related art and the control apparatuses for a vehicle according to the first to third embodiments of the present disclosure.

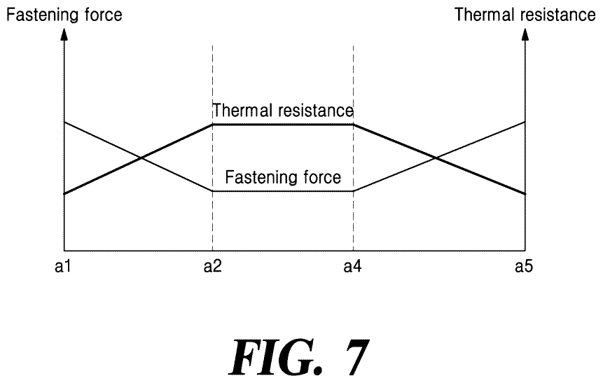

FIG. 7 is a graph showing thermal resistance according to screw fastening force of the control apparatus for a vehicle according to the third embodiment of the present disclosure.

Referring to FIG. 2 to FIG. 7, a control apparatus for a vehicle according to a first embodiment of the present disclosure may include all or some of a first heat generation source 120, a second heat generation source 110, a circuit board 140, and a heat transfer member 200, a third thermal interface material 310, and a heat sink 130 according to the first embodiment.

The first heat generation source 120, the second heat generation source 110, and the like may be mounted on the circuit board 140.

The first heat generation source 120 may include all or some of a first chip 121 and a first thermal interface material 122. The first chip 121 may be an electric part such as a device that emits heat energy.

The first thermal interface material 122 may be disposed on the first chip 121. The first thermal interface material 122 can perform a function of adjusting the height of a device, a function of forming a heat transfer path, and the like. The first thermal interface material 122 may be a silicone pad, silicone grease, a graphite sheet, and the like. However, the material of the first thermal interface material 122 is not necessarily limited thereto.

The second heat generation source 110 may include all or some of a second chip 111 and a second thermal interface material 112. The second heat generation source 110 may be disposed to be surrounded by a plurality of first heat generation sources 120. The second chip 111 may be an electric part such as a device that emits heat energy. The second chip 111 can emit relatively more heat energy than the first chip 121.

The second thermal interface material 112 can perform a function of adjusting the height of a device, a function of forming a heat transfer path, and the like. The second thermal interface material 112 may be a silicone pad, silicone grease, a graphite sheet, and the like. However, the material of the second thermal interface material 112 is not necessarily limited thereto.

The heat transfer member 200 according to the first embodiment may be configured to uniformly dissipate heat energy emitted from the first heat generation source 120 and the second heat generation source 110 to the heat sink 130. The heat transfer member 200 according to the first embodiment may be made of a material such as metal. However, the material of the heat transfer member 200 according to the first embodiment is not necessarily limited thereto. The heat transfer member 200 according to the first embodiment may include a first plate 202 and a second plate 203. The first plate 202 is in contact with the top surface of the first heat generation source 120 and may include a through-hole 201 at a position corresponding to the second heat generation source 110. The second plate 203 may be configured to form a step in the height direction from the first plate 202. Since the second plate 203 forms a step with respect to the first plate 202, contact between the first plate 202 and the heat sink 130 can be prevented. Accordingly, an air insulation layer can be formed between the first plate 202 and the heat sink 130. Therefore, it is possible to distribute the heat transfer path of the heat energy emitted from the first heat generation source 120 and uniformly dissipate heat to the entire area of the heat sink 130.

Referring to FIG. 3, the second heat generation source 110 that is a relatively high-heat-generating device may be disposed to pass through the through-hole 201 formed in the first plate 202 to be in direct contact with the heat sink 130. Accordingly, the heat energy emitted from the second heat generation source 110 can be directly dissipated to at least any one of the area between a2 and a3 or the area between a3 and a4 of the heat sink 130.

The heat energy emitted from the first heat generation source 120 can be dissipated to the heat sink 130 using the heat transfer member 200 according to the first embodiment. The heat energy emitted from the first heat generation source 120 can be dissipated to at least any one of the area between a1 and a2 or the area between a4 and a5 of the heat sink 130 through the first plate 202 and the second plate 203.

Referring to FIG. 6, P1 indicates temperature according to the position of a heat sink 130 of a control apparatus for a vehicle according to the related art. N1 indicates temperature according to the position of the heat sink 130 of the control apparatus for a vehicle according to the first embodiment of the present disclosure. By disposing the heat transfer member 200 according to the first embodiment, it is possible to uniformly dissipate heat to the entire of the heat sink 130.

The third thermal interface material 310 can perform a function of adjusting the height of a device, a function of forming a heat transfer path, and the like. The third thermal interface material 310 may be a silicone pad, silicone grease, a graphite sheet, and the like. However, the material of the third thermal interface material 310 is not necessarily limited thereto.

The heat sink 130 may be configured to discharge the heat energy emitted from the first heat generation source 120 and the second heat generation source 110 to the outside of the control apparatus for a vehicle.

A control apparatus for a vehicle according to a second embodiment of the present disclosure may include all or some of a first heat generation source 120, a second heat generation source 110, a circuit board 140, and a heat transfer member 400, a third thermal interface material 310, and a heat sink 130 according to the second embodiment.

The components according to the second embodiment of the present disclosure may be the same as the components according to the first embodiment except for the components to be specifically described hereafter, so detailed description of the same matters is omitted.

The heat transfer member 400 according to the second embodiment may include a plate formed to extend outward from the second heat generation source 110, and a through-hole 201 that is a predetermined area of the plate and is formed at a position corresponding to the second heat generation source 110.

Unlike the heat transfer member 200 according to the first embodiment, the heat transfer member 400 according to the second embodiment may be configured in an entirely flat shape without a step. The heat transfer member 400 according to the second embodiment may include an insulation-intended section S2 and a conduction-enhancing section S1.

The heat transfer member 400 according to the second embodiment may be configured to form a heat dissipation path using the principle of contact thermal resistance based on surface roughness. The greater the surface roughness, the higher the contact thermal resistance may become. This is because as the surface roughness increases, the contact area decreases and a gap or a fine air layer may be formed between contact surfaces.

Referring to FIG. 4, the insulation-intended section S2 may be configured with a rough surface to increase thermal resistance. By forming the surface of the insulation-intended section S2 to be rough, a gap or an air layer is formed between the insulation-intended section S2 of the heat transfer member 400 according to the second embodiment and the heat sink 130, whereby it is possible to increase thermal resistance. The insulation-intended section S2 may be formed in an area corresponding to the first heat generation source 120.

The conduction-enhancing section S1 may be configured with a smooth surface to decrease thermal resistance. Accordingly, the heat energy emitted from the first heat generation source 120 can be dissipated to at least any one of the area between a1 and a2 and the area between a4 and a5 of the heat sink 130 through the conduction-enhancing section S1 of the heat transfer member 400 and the third thermal interface material 310 according to the second embodiment.

A control apparatus for a vehicle according to a third embodiment of the present disclosure may include all or some of a first heat generation source 120, a second heat generation source 110, a circuit board 140, and a heat transfer member 410, a first screw 510, a second screw 520, a third thermal interface material 310, and a heat sink 130 according to the third embodiment.

The components according to the third embodiment of the present disclosure may be the same as the components according to the first embodiment or the second embodiment except for the components to be specifically described hereafter, so detailed description of the same matters is omitted.

The heat transfer member 410 according to the third embodiment may include a plate extending outward from the second heat generation source 110, and a through-hole 201 that is a predetermined area of the plate and is formed at a position corresponding to the second heat generation source 110. The heat transfer member 410 according to the third embodiment may be configured in an entirely flat shape without a step. The heat transfer member 410 according to the third embodiment may be formed with a surface that is entirely smooth, unlike the heat transfer member 400 according to the second embodiment.

The heat transfer member 410 according to the third embodiment may be configured to form a heat dissipation path using the difference in fastening force of screws. Referring to FIG. 7, the stronger the fastening of a plurality of objects, the tighter they can be in contact with each other, and accordingly, the thermal resistance of the contact area can be decreased.

Referring to FIG. 5, the control apparatus for a vehicle according to the third embodiment of the present disclosure may include a first screw 510 fastened to an area adjacent to an area where a heat dissipation path is intended to be formed. The first screw 510 can couple the heat transfer member 410, the third thermal interface material 310, and the heat sink 130 according to the third embodiment. By fastening the first screw 510, the heat transfer member 410, the third thermal interface material 310, and the heat sink 130 according to the third embodiment can be brought into closer contact with each other in an area adjacent to the first screw 510. Accordingly, the heat energy emitted from the first heat generation source 120 can be dissipated to at least any one of the area between a1 and a2 or the area between a4 and a5 of the heat sink 130 through the heat transfer member 410 and the third thermal interface material 310 according to the third embodiment.

The second screw 520 is fastened to an area adjacent to the second heat generation source 110, so it can couple the heat transfer member 410 and the heat sink 130 according to the third embodiment. The fastening force of the first screw 510 may be greater than the fastening force of the second screw 520. Accordingly, it is possible to stably couple the heat transfer member 410 and the heat sink 130 according to the third embodiment and separate heat dissipation paths.

The foregoing descriptions are merely illustrative of the technical idea of the present embodiment, and various modifications and variations may be made by those skilled in the art without departing from the essential characteristics of the present embodiment. Therefore, the present embodiments are not intended to limit the technical idea of the present embodiments, but are intended to be illustrative, and the scope of the technical idea of this embodiment is not limited by these embodiments. The protection scope of the present embodiment is to be construed according to the following claims, and all technical ideas within the scope equivalent thereto are construed as being included in the scope of rights of the present embodiment.

What is claimed is:

1. A control apparatus for a vehicle, comprising:
a first heat generation source including a first chip emitting heat energy and a first thermal interface material disposed on the first chip;
a second heat generation source including a second chip emitting more heat energy than the first chip and a second thermal interface material disposed on the second chip;
a circuit board on which the first heat generation source and the second heat generation source are mounted;
a heat transfer member including a plate extending outward from the second heat generation source and a through-hole formed at a position corresponding to the second heat generation source, and disposed on the first heat generation source;
a third thermal interface material disposed on an end of the heat transfer member; and
a heat sink disposed in contact with the second heat generation source and the third thermal interface material to dissipate heat.

2. The control apparatus of claim 1, wherein the plate includes:
a first plate being in contact with the first heat generation source; and
a second plate forming a step in a height direction from the first plate.

3. The control apparatus of claim 2, wherein the first plate and the heat sink are spaced from each other, thereby forming an air insulation layer.

4. The control apparatus of claim 1, wherein the plate includes:
an insulation-intended section having a rough surface to increase thermal resistance; and
a conduction-enhancing section having a smooth surface to decrease thermal resistance.

5. The control apparatus of claim 1, wherein the heat sink has a rough surface in an area facing the first heat generation source.

6. The control apparatus of claim 1, further comprising a first screw coupling the plate, the third thermal interface material, and the heat sink.

7. The control apparatus of claim 6, further comprising a second screw coupling the plate and the heat sink in an inward direction facing the second heat generation source from the first screw,
wherein fastening force of the first screw is greater than fastening force of the second screw.

8. The control apparatus of claim 1, wherein the heat transfer member is made of a metallic material.
